(19) United States
(12) Patent Application Publication
(10) Pub. No.: US 2025/0254982 A1
(43) Pub. Date: Aug. 7, 2025

(54) SEMICONDUCTOR DEVICE

(71) Applicant: FUJI ELECTRIC CO., LTD., Kanagawa (JP)

(72) Inventors: Toru MURAMATSU, Matsumoto-city (JP); Tatsuya NAITO, Matsumoto-city (JP); Yosuke SAKURAI, Azumino-city (JP)

(21) Appl. No.: 19/185,139

(22) Filed: Apr. 21, 2025

Related U.S. Application Data
(63) Continuation of application No. PCT/JP2024/007636, filed on Feb. 29, 2024.

(30) Foreign Application Priority Data
May 16, 2023 (JP) 2023-080573

(51) Int. Cl. H10D 84/80; H10D 8/00; H10D 12/00; H10D 62/10; H10D 62/60

(52) U.S. Cl. CPC H10D 84/811; H10D 8/422; H10D 12/481; H10D 62/103; H10D 62/127; H10D 62/60

(57) ABSTRACT

Provided is a semiconductor device including a transistor portion and a diode portion, including: a plurality of trench portions provided at a front surface of a semiconductor substrate and including a gate trench portion; an emitter region of a first conductivity type provided above a base region and having a doping concentration higher than that of a drift region; and a first accumulation region of the first conductivity type provided below the base region and having a doping concentration higher than that of the drift region; wherein the transistor portion includes a boundary region provided adjacent to the diode portion and including a boundary mesa portion, wherein the boundary region includes the emitter region, a second accumulation region of the first conductivity type having a doping concentration higher than that of the first accumulation region, and the gate trench portion provided in contact with the boundary mesa portion.

The contents of the following patent application(s) are incorporated herein by reference:
NO. 2023-080573 filed in JP on May 16, 2023
NO. PCT/JP2024/007636 filed in WO on Feb. 29, 2024.

### BACKGROUND

### 1. Technical Field

The present invention relates to a semiconductor device.

### 2. Related Art

Patent document 1 describes that “a peak value of a doping concentration of an accumulation region 16 in a narrow mesa portion 61 may be higher than a peak value of the doping concentration of the accumulation region 16 in a mesa portion 60”.

### PRIOR ART DOCUMENTS

### Patent Documents

Patent Document 1: International Publication No. 2019-220940
Patent Document 2: Japanese Patent Application Publication No. 2020-177973
Patent Document 3: International Publication No. 2018-030440

### BRIEF DESCRIPTION OF THE DRAWINGS

FIG. 1 illustrates an example of a top view of a semiconductor device 100.

FIG. 2A illustrates an example of a cross section of the semiconductor device 100.

FIG. 2B illustrates an example of a cross section of the semiconductor device 100.

FIG. 2C illustrates an example of a cross section of the semiconductor device 100.

FIG. 3 illustrates an example of a cross section of a semiconductor device 200.

FIG. 4A illustrates an example of a top view of a semiconductor device 500 of a comparative example.

FIG. 4B illustrates an example of a cross section of the semiconductor device 500 of the comparative example.

FIG. 4C illustrates an example of a cross section of a semiconductor device 600 of a comparative example.

FIG. 5 illustrates a relationship between steady-state loss and reverse recovery loss.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. It is to be noted that a +Z axis direction and a −Z axis direction are directions opposite to each other. If the Z axis direction is described without describing the signs, it means that the direction is parallel to the +Z axis and the −Z axis.

In the present specification, a surface parallel to the upper surface of the semiconductor substrate is referred to as an XY surface, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. It is to be noted that as used in the present specification, a view of the semiconductor substrate in the Z axis direction is referred to as a planar view. In addition, in the present specification, a direction parallel to the upper surface and the lower surface of the semiconductor substrate may be referred to as a horizontal direction, including the X axis direction and the Y axis direction.

Each embodiment shows an example in which a first conductivity type is set as an N type, and a second conductivity type is set as a P type; however, the first conductivity type may be the P type, and the second conductivity type may be the N type. In this case, conductivity types of a substrate, a layer, a region, and the like in each embodiment respectively have opposite polarities.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as the P type or the N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type.

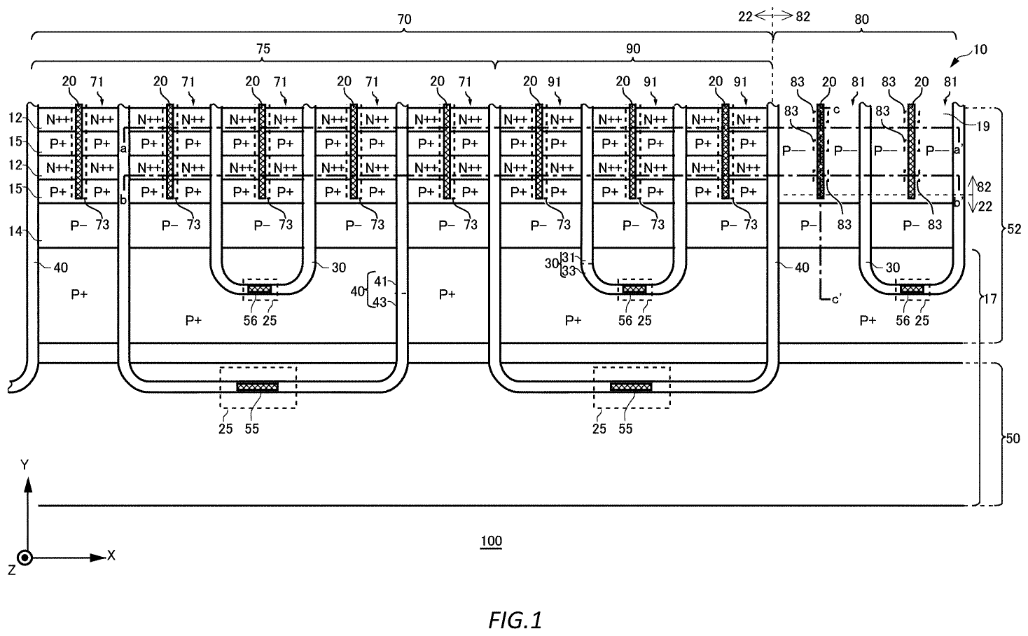

FIG. 1 illustrates an example of a top view of a semiconductor device 100. The semiconductor device 100 of the present example is a semiconductor chip including a transistor portion 70 and a diode portion 80. For example, the semiconductor device 100 is a reverse conducting IGBT (RC-IGBT). The transistor portion 70 of the present example includes a boundary region 90 in a part in direct contact with the diode portion 80.

The transistor portion 70 is a region obtained by projecting a collector region 22 provided at a back surface side of a semiconductor substrate 10 onto an upper surface of the semiconductor substrate 10. The collector region 22 will be described below. The transistor portion 70 includes a transistor such as an IGBT. The transistor portion 70 of the present example includes a main region 75.

The main region 75 is a region other than the boundary region 90 within the transistor portion 70. In the main region 75, a first accumulation region 16 described below is provided, and a second accumulation region 26 is not provided. During operation of the semiconductor device 100, a channel region is formed in the main region 75, and the main region 75 functions as an active region.

The diode portion 80 is a region where a cathode region 82 provided at a back surface of the semiconductor substrate 10 is projected onto the upper surface of the semiconductor substrate 10. The cathode region 82 has the first conductivity type. The cathode region 82 of the present example is of the N type as an example. The diode portion 80 includes a diode such as a free wheel diode (FWD) provided adjacent to the transistor portion 70 at the upper surface of the semiconductor substrate 10.

FIG. 1 illustrates a region around a chip end portion which is an edge side of the semiconductor device 100, and other regions are omitted. For example, an edge termination structure portion may be provided in a region at a negative side in the Y axis direction of the semiconductor device 100 of the present example. The edge termination structure portion reduces electric field strength at an upper surface side of the semiconductor substrate 10. The edge termination structure portion has, for example, a guard ring, a field plate, a RESURF, and a structure combining these. It is to be noted that although the present example describes an edge at the negative side in the Y axis direction for convenience, the same applies to other edges of the semiconductor device 100. The edge termination structure portion may be provided so as to surround an active portion including the transistor portion 70 and the diode portion 80.

The semiconductor substrate 10 may be a silicon substrate, a silicon carbide substrate, or a nitride semiconductor substrate such as gallium nitride, or the like. The semiconductor substrate 10 of the present example is the silicon substrate.

The semiconductor device 100 of the present example includes a gate trench portion 40, a dummy trench portion 30, an emitter region 12, a base region 14, a contact region 15, a well region 17, an anode region 19, and a trench contact portion 20, at a front surface 21 of the semiconductor substrate 10. The front surface 21 will be described below. In addition, the semiconductor device 100 of the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, the contact region 15, the well region 17, the anode region 19, and the trench contact portion 20. In addition, the gate metal layer 50 is provided above the gate trench portion 40 and the well region 17.

The emitter electrode 52 and the gate metal layer 50 are formed of a material including metal. At least a partial region of the emitter electrode 52 may be formed of metal such as aluminum (Al), or an alloy including aluminum, for example, a metal alloy such as an aluminum-silicon alloy (AlSi) and an aluminum-silicon-copper alloy (AlSiCu). At least a partial region of the gate metal layer 50 may be formed of metal such as aluminum (Al), or an alloy including aluminum, for example, a metal alloy such as an aluminum-silicon alloy (AlSi) and an aluminum-silicon-copper alloy (AlSiCu). The emitter electrode 52 and the gate metal layer 50 may have barrier metal formed of titanium, a titanium compound, or the like in a lower layer of a region formed of aluminum or an alloy including aluminum, or the like. The emitter electrode 52 and the gate metal layer 50 are provided separately from each other.

The emitter electrode 52 and the gate metal layer 50 are provided with an interlayer dielectric film 38 sandwiched therebetween, above the semiconductor substrate 10. The interlayer dielectric film 38 is omitted in FIG. 1. The trench contact portion 20, a contact hole 55, and a contact hole 56 are provided penetrating through the interlayer dielectric film 38.

The trench contact portion 20 is provided to extend from an upper surface of the interlayer dielectric film 38 in the depth direction of the semiconductor substrate 10. The trench contact portion 20 has a bottom portion and a side portion. The trench contact portion 20 electrically connects the emitter electrode 52 and the semiconductor substrate 10. The trench contact portion 20 is provided to extend in a trench extending direction. The trench contact portion 20 of the present example is arranged in a striped pattern along the gate trench portion 40 and the dummy trench portion 30.

The trench contact portion 20 is formed at an upper surface of each region of the emitter region 12 and the contact region 15 in the transistor portion 70. The trench contact portion 20 is not provided above the well regions 17 provided at both ends of the Y axis direction. In this manner, one or more trench contact portions 20 are formed in an interlayer dielectric film. The one or more trench contact portions 20 may be provided to extend in an extending direction.

The trench contact portion 20 is provided above the anode region 19 in the diode portion 80. The trench contact portion 20 is provided at an upper surface of the contact region 15 and the anode region 19 in the boundary region 90. None of the trench contact portions 20 is provided above the well regions 17 provided at both ends of the Y axis direction.

A plug region 73 is provided below the trench contact portion 20 in the transistor portion 70. In addition, a plug region 83 is provided below the trench contact portion 20 in the diode portion 80. The plug region 73 and the plug region 83 will be described below in detail.

The contact hole 55 connects the gate metal layer 50 with a gate conductive portion inside the transistor portion 70. Inside the contact hole 55, a plug formed of tungsten or the like may be formed via a barrier metal.

The contact hole 56 connects the emitter electrode 52 with a dummy conductive portion inside the dummy trench portion 30. Inside the contact hole 56, a plug formed of tungsten or the like may be formed via a barrier metal.

A connecting portion 25 electrically connects a front surface side electrode such as the emitter electrode 52 or the gate metal layer 50 to the semiconductor substrate 10. In an example, the connecting portion 25 is provided between the gate metal layer 50 and the gate conductive portion. The connecting portion 25 is also provided between the emitter electrode 52 and the dummy conductive portion. The connecting portion 25 is formed of a conductive material such as polysilicon doped with an impurity. The connecting portion 25 of the present example is polysilicon doped with an impurity of the N type (N+). The connecting portion 25 is provided above the front surface 21 of the semiconductor substrate 10 via a dielectric film such as an oxide film, or the like.

The gate trench portions 40 are arrayed at predetermined intervals along a predetermined array direction (the X axis direction in the present example). The gate trench portion 40 of the present example may have two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 may be formed to have a curved shape. Connecting end portions of the two extending parts 41 of the gate trench portion 40 can reduce electric field strength at the end portions of the extending parts 41. The gate metal layer 50 may be connected to the gate conductive portion at the connecting part 43 of the gate trench portion 40.

The dummy trench portion 30 is a trench portion electrically connected to the emitter electrode 52. Similarly to the gate trench portions 40, the dummy trench portions 30 are arrayed at predetermined intervals along a predetermined array direction (the X axis direction in the present example). The dummy trench portion 30 of the present example may have, similarly to the gate trench portion 40, a U shape at the front surface 21 of the semiconductor substrate 10. That is, the dummy trench portion 30 may have two extending parts 31 which extend along the extending direction and a connecting part 33 which connects the two extending parts 31.

Within the transistor portion 70 of the present example, the main region 75 has a structure in which a pattern in which two dummy trench portions 30 are arranged between two gate trench portions 40 is repeatedly arrayed. That is, the transistor portion 70 of the present example has the gate trench portions 40 and the dummy trench portions 30 at a ratio of 1:1. For example, the transistor portion 70 has two extending parts 31 between two extending parts 41. In addition, the transistor portion 70 has a place where two extending parts 41 are adjacent to one another.

It is to be noted that the ratio between the gate trench portions 40 and the dummy trench portions 30 is not limited to that in the present example. The ratio between the gate trench portions 40 and the dummy trench portions 30 may be 2:3 or 2:4. In addition, the transistor portion 70 may not have the dummy trench portions 30 with all trench portions being the gate trench portions 40.

Within the transistor portion 70 of the present example, the gate trench portion 40 and the dummy trench portion 30 are provided in the boundary region 90. By providing the gate trench portion 40, an area of the active region of the transistor portion 70 can be improved, and an operation efficiency of the semiconductor device 100 can be improved.

The well region 17 is a region of the second conductivity type which is provided more at a front surface 21 side of the semiconductor substrate 10 than a drift region 18 which will be described below. The well region 17 is an example of a well region provided at the edge side of the semiconductor device 100. The well region 17 is of the P+ type as an example. The well region 17 is formed in a predetermined range from an end portion of the active portion at a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 at a gate metal layer 50 side are formed in the well region 17. Bottoms of ends in the extending direction of the gate trench portion 40 and the dummy trench portion 30 may be covered with the well region 17.

A mesa portion 71 is a mesa portion provided in direct contact with the trench portion in a plane parallel to the front surface 21 of the semiconductor substrate 10. The mesa portion may be a part of the semiconductor substrate 10 sandwiched between two adjacent trench portions, and may be a part from the front surface 21 of the semiconductor substrate 10 to a depth of the lowermost bottom portion of each trench portion. An extending part of each trench portion may be defined as one trench portion. That is, a region sandwiched between two extending parts may be defined as a mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the contact region 15 at the front surface 21 of the semiconductor substrate 10. In the mesa portion 71, the emitter regions 12 and the contact regions 15 are alternately provided in the extending direction.

The base region 14 is a region of the second conductivity type which is provided at the front surface 21 side of the semiconductor substrate 10. The base region 14 is of the P-type as an example. The base regions 14 may be provided at both end portions of the mesa portion 71 in the Y axis direction at the front surface 21 of the semiconductor substrate 10. It is to be noted that FIG. 1 illustrates only one end portion of the base region 14 in the Y axis direction.

The emitter region 12 is a region of the first conductivity type which is provided at the front surface 21 of the semiconductor substrate 10 and has a doping concentration higher than that of the drift region 18. The emitter region 12 of the present example is of the N++ type as an example. An example of a dopant of the emitter region 12 is arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71.

In addition, the emitter region 12 may be or may not be in contact with the dummy trench portion 30. The emitter region 12 of the present example is in contact with the dummy trench portion 30.

The contact region 15 is a region of the second conductivity type having a higher doping concentration than that of the base region 14. The contact region 15 of the present example is of the P+ type as an example. The contact region 15 of the present example is provided at the front surface 21 in the mesa portion 71. The contact region 15 may be provided in the X axis direction from one to another of the two trench portions sandwiching the mesa portion 71. The contact region 15 may be or may not be in contact with the gate trench portion 40 or the dummy trench portion 30. The contact region 15 of the present example is in contact with the dummy trench portion 30 and the gate trench portion 40.

The boundary region 90 is a region which is provided in the transistor portion 70 and is in direct contact with the diode portion 80. The boundary region 90 has the emitter region 12 and the contact region 15. The boundary region 90 of the present example is arranged so that both ends in the X axis direction are the gate trench portion 40.

A structure at the front surface 21 side of the boundary region 90 may correspond to a structure at the front surface 21 side of the main region 75. That is, during operation of the semiconductor device 100, a channel region may be formed in the boundary region 90, and the boundary region 90 may also function as an active region. The boundary region 90 may have the same configuration as the main region 75, except that the second accumulation region 26 described below is provided instead of the first accumulation region 16.

A mesa portion 91 is provided in the boundary region 90. The mesa portion 91 has the emitter region 12 and the contact region 15 at the front surface 21 of the semiconductor substrate 10. The mesa portion 91 of the present example has the base region 14 and the well region 17 at the negative side of the Y axis direction. The mesa portion 91 may also have the base region 14 and the well region 17 at the positive side of the Y axis direction.

In the present example, a plurality of mesa portions 91 is provided in the boundary region 90. One mesa portion 91 may be provided in the boundary region 90. In a trench array direction (X axis direction) of the plurality of trench portions, a width of the boundary region 90 may be 30 μm or more and 150 μm or less.

A mesa portion 81 is provided in a region sandwiched between adjacent dummy trench portions 30 in the diode portion 80. The mesa portion 81 has the anode region 19 at the front surface 21 of the semiconductor substrate 10. The mesa portion 81 of the present example has the anode region 19 and the well region 17 at the negative side of the Y axis direction.

The anode region 19 is a region of the second conductivity type. A doping concentration of the anode region 19 may be lower than a doping concentration of the base region 14. The anode region 19 of the present example is of a P−-type as an example. The anode region 19 of the present example is provided at the front surface 21 in the mesa portion 81. The anode region 19 may be provided in the X axis direction from one to another of the two dummy trench portions 30 sandwiching the mesa portion 81. The anode region 19 may or may not be in contact with the gate trench portion 40 at the boundary between the transistor portion 70 and the diode portion 80. The anode region 19 of the present example is in contact with the gate trench portion 40 at the boundary between the transistor portion 70 and the diode portion 80.

The doping concentration of the anode region 19 of the present example may be 1E16 cm⁻³ or more and 1E17 cm⁻³ or less. It is to be noted that the E means 10 to the power of, for example, 1E16 cm⁻³ means 1×10¹⁶ cm⁻³. The anode region 19 may have a peak of the doping concentration in the depth direction of the semiconductor substrate 10. In addition, in the depth direction of the semiconductor substrate 10, a lower end of the anode region 19 may have a same depth as a lower end of the base region 14, or may be at a deeper position than that of the lower end of the base region 14.

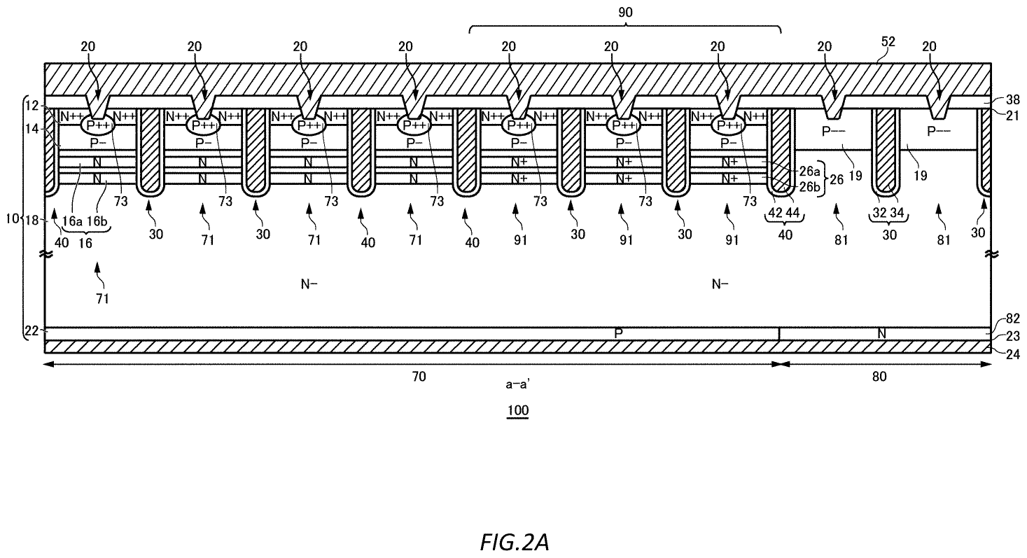

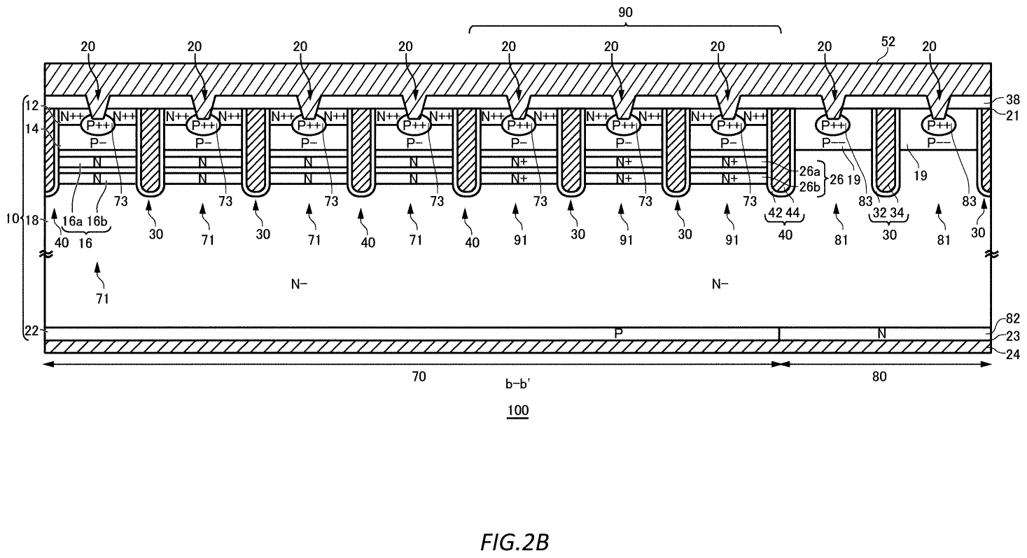

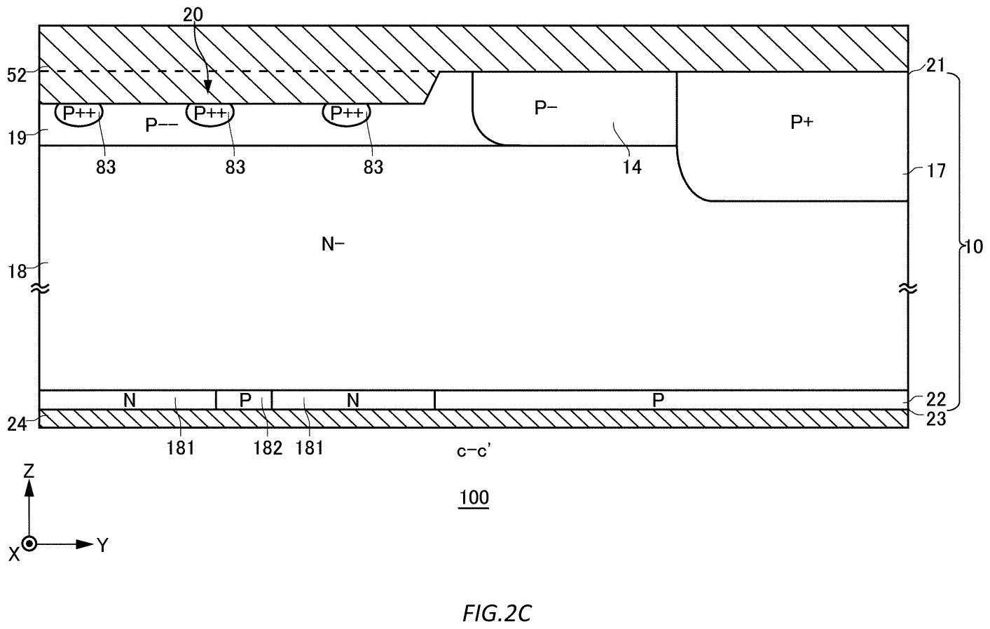

FIG. 2A is an example of an a-a′ cross section in FIG. 1. The a-a′ cross section is an XZ plane which does not pass through the plug region 83 described below in the transistor portion 70 and the diode portion 80. The semiconductor device 100 of the present example has the semiconductor substrate 10, the drift region 18, the first accumulation region 16, the second accumulation region 26, the interlayer dielectric film 38, the emitter electrode 52 and a collector electrode 24 on the a-a′ cross section. The emitter electrode 52 is formed above the semiconductor substrate 10 and the interlayer dielectric film 38.

The drift region 18 is a region of the first conductivity type which is provided in the semiconductor substrate 10. The drift region 18 of the present example is of the N-type as an example. The drift region 18 may be a region which has remained without other doping regions formed in the semiconductor substrate 10. That is, a doping concentration of the drift region 18 may be a doping concentration of the semiconductor substrate 10.

The collector region 22 is provided at a back surface 23 of the semiconductor substrate 10 in the transistor portion 70. The collector region 22 is a region of the second conductivity type which has a doping concentration higher than that of the base region 14. The collector region 22 of the present example is of the P type as an example.

The cathode region 82 is provided at the back surface 23 of the semiconductor substrate 10 in the diode portion 80. The cathode region 82 is a region of the first conductivity type which has a higher doping concentration than that of the drift region 18. The cathode region 82 of the present example is of the N type as an example.

A boundary between the collector region 22 and the cathode region 82 is the boundary between the transistor portion 70 and the diode portion 80. That is, the collector region 22 is provided below the boundary region 90 of the present example. In addition, the cathode region 82 may have a first cathode portion 181 and a second cathode portion 182 which will be described below in detail.

The collector electrode 24 is formed at the back surface 23 of the semiconductor substrate 10. The collector electrode 24 is formed of a conductive material such as metal.

The base region 14 is a region of the second conductivity type provided above the drift region 18. The doping concentration of the base region 14 may be higher than the doping concentration of the anode region 19. The doping concentration of the base region 14 may be 3E16 cm⁻³ or more and 1E18 cm⁻³ or less. The base region 14 may be provided below the emitter region 12. The base region 14 is provided in contact with the gate trench portion 40. The base region 14 may be provided in contact with the dummy trench portion 30.

The first accumulation region 16 is a region of the first conductivity type which is provided below the base region 14 in the depth direction of the semiconductor substrate 10. The first accumulation region 16 of the present example is of the N type as an example. The first accumulation region 16 is provided in the main region 75 of the transistor portion 70, and is not provided in the diode portion 80 and the boundary region 90. By providing the first accumulation region 16, a carrier injection enhancement effect (IE effect) can be increased, and an ON voltage of the transistor portion 70 can be reduced.

A plurality of first accumulation regions 16 may be provided in the depth direction of the semiconductor substrate 10. In an example, the first accumulation region 16 is provided in two stages as first accumulation regions 16a and 16b. Thicknesses of the first accumulation regions 16a and 16b in the depth direction of the semiconductor substrate 10 may be the same or different. The drift region 18 may be provided between the first accumulation regions 16a and 16b.

The first accumulation region 16 may be provided in multiple stages of three stages or more. In this case, among the first accumulation regions 16, a lower end of the first accumulation region 16 provided at a side closest to the back surface 23 may be positioned above the bottom portion of the adjacent trench portion. By providing the first accumulation region 16 in multiple stages, clamp tolerance can be improved.

The second accumulation region 26 is a region of the first conductivity type which is provided below the base region 14 in the depth direction of the semiconductor substrate 10. The second accumulation region 26 of the present example is of the N+ type as an example. The second accumulation region 26 is provided in the boundary region 90, and is not provided in the diode portion 80 and the main region 75. By providing the second accumulation region 26, implantation of holes into the diode portion 80 can be suppressed, and reverse recovery loss Err can be reduced. In addition, by not providing either the first accumulation region 16 or the second accumulation region 26 in the diode portion 80, an increase in steady-state loss Vf of the diode portion can be suppressed.

A doping concentration of the second accumulation region 26 may be higher than a doping concentration of the first accumulation region 16. By making the doping concentration of the second accumulation region 26 higher than the doping concentration of the first accumulation region 16, the reverse recovery loss Err can be reduced. The doping concentration of the first accumulation region 16 may be 1E16 cm⁻³ or more and 1E18 cm⁻³ or less, and the doping concentration of the second accumulation region 26 may be 1E16 cm⁻³ or more and 1E20 cm⁻³ or less. The doping concentration of the second accumulation region 26 may be lower than a doping concentration of the emitter region 12.

A plurality of second accumulation regions 26 may be provided in the depth direction of the semiconductor substrate 10. In an example, the second accumulation region 26 is provided in two stages as second accumulation regions 26a and 26b. Thicknesses of the second accumulation regions 26a and 26b in the depth direction of the semiconductor substrate 10 may be the same or different. The drift region 18 may be provided between the second accumulation regions 26a and 26b.

The second accumulation region 26 may have one or more peaks of the doping concentration in the depth direction of the semiconductor substrate 10. In the present example, the second accumulation region 26 is provided in two stages as the second accumulation regions 26a and 26b, and has two peaks of the doping concentration. The second accumulation region 26 may be provided in multiple stages of three stages or more. A number of stages of the second accumulation region 26 may be the same as or different from a number of stages of the first accumulation region 16. By making the second accumulation region 26 have a plurality of peaks of the doping concentration, a concentration at each peak can be reduced while increasing a dose amount, and lowering of the clamp tolerance can be suppressed.

A thickness of the second accumulation region 26 in the depth direction of the semiconductor substrate 10 may be smaller than a thickness of the base region 14. In the present specification, the thickness of the second accumulation region 26 may be a length in the depth direction of the semiconductor substrate 10 from an upper end of the second accumulation region 26 at a side closest to the front surface 21 to a lower end of the second accumulation region 26 at a side closest to the back surface 23. In an example, the thickness of the second accumulation region 26 is 0.5 μm or more and 4.0 μm or less.

One or more gate trench portions 40 and one or more dummy trench portions 30 are provided at the front surface 21. Each trench portion is provided from the front surface 21 to the drift region 18. For regions provided with at least any one of the emitter region 12, the base region 14, the contact region 15, the first accumulation region 16, the anode region 19, and the second accumulation region 26, each trench portion also penetrates these regions to reach the drift region 18. A configuration in which a trench portion penetrates a doping region is not limited to a configuration which is manufactured by forming a trench portion after forming a doping region. The configuration of the trench portion penetrating the doping region includes a configuration of the doping region being formed between the trench portions after forming the trench portions.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a side of the mesa portion 71 by sandwiching the gate dielectric film 42 in the depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have a same structure as that of the gate trench portion 40. The dummy trench portion 30 has a dummy trench, a dummy dielectric film 32, and a dummy conductive portion 34 which are formed at the front surface 21 side. The dummy dielectric film 32 is formed to cover an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The interlayer dielectric film 38 is provided at the front surface 21. The emitter electrode 52 is provided above the interlayer dielectric film 38. The interlayer dielectric film 38 is provided with one or more trench contact portions 20 to electrically connect the emitter electrode 52 and the semiconductor substrate 10. Similarly to the trench contact portion 20, the contact hole 55 and the contact hole 56 may also be provided to penetrate the interlayer dielectric film 38. The trench contact portion 20 penetrates the interlayer dielectric film 38 and reaches the emitter region 12 or the anode region 19. The trench contact portion 20 electrically connects the emitter electrode 52 and the semiconductor substrate 10. In the present example, a depth of a lower end of the trench contact portion 20 is shallower than a depth of a lower end of the emitter region 12. In this way, an increase of a threshold Vth of the semiconductor device 100 can be suppressed, and variations in characteristics of the semiconductor device 100 can be suppressed.

The depth of the lower end of the trench contact portion 20 may be deeper than the depth of the lower end of the emitter region 12. By making the depth of the lower end of the trench contact portion 20 deeper than the depth of the lower end of the emitter region 12, latch-up resistance can be improved. The depth of the lower end of the trench contact portion 20 may be 0.3 μm or more and 0.5 μm or less from the front surface 21 of the semiconductor substrate 10.

The plug region 73 is a region of the second conductivity type provided below the bottom portion of the trench contact portion 20 in the transistor portion 70 and having a doping concentration higher than that of the base region 14. The doping concentration of the plug region 73 may be 1E19 cm⁻³ or more and 1E22 cm⁻³ or less. The plug region 73 of the present example is of the P++ type as an example. The plug region 73 may be provided so as to cover the bottom portion and a part of a side wall of the trench contact portion 20.

In an example, the plug region 73 is formed by implantation of a dopant via the trench contact portion 20. The trench contact portion 20 may be provided after the plug region 73 is previously formed.

The doping concentration of the plug region 73 may be higher than the doping concentration of the contact region 15. In addition, the doping concentration of the plug region 73 may be the same as the doping concentration of the contact region 15.

The plug regions 73 are repeatedly provided in a trench extending direction in the mesa portion 71 and the mesa portion 91. That is, the plug regions 73 are provided in a striped pattern in the mesa portion 71 and the mesa portion 91. By providing the plug region 73, resistance of the bottom portion of the trench contact portion 20 in the transistor portion 70 can be lowered, and latch-up destruction can be suppressed.

FIG. 2B is an example of a b-b′ cross section in FIG. 1. The b-b′ cross section is an XZ plane which passes through the plug region 83 in the transistor portion 70 and the diode portion 80. A configuration included on the b-b′ cross section may be the same as on the a-a′ cross section except for the plug region 83.

The plug region 83 is a region of the second conductivity type provided below the bottom portion of the trench contact portion 20 in the diode portion 80 and having a doping concentration higher than that of the anode region 19. The doping concentration of the plug region 83 may be 1E19 cm⁻³ or more and 1E22 cm⁻³ or less. The doping concentration of the plug region 83 may be the same as the doping concentration of the plug region 73 in the transistor portion. The plug region 83 of the present example is of the P++ type as an example. The plug region 83 may be provided so as to cover the bottom portion and a part of the side wall of the trench contact portion 20.

The plug regions 83 are selectively provided in the trench extending direction in the mesa portion 81. That is, the plug regions 83 are provided in a dotted pattern in the mesa portion 81. The plug regions 83 may be selectively provided so as to be at equal intervals in the trench extending direction.

In an example, the plug region 83 is formed by implantation of a dopant via the trench contact portion 20. The trench contact portion 20 may be provided after the plug region 83 is previously formed.

By providing the plug region 83, resistance of the bottom portion of the trench contact portion 20 in the diode portion 80 can be lowered, and the steady-state loss Vf can be lowered. Although the steady-state loss Vf increases when the first cathode portion 181 and the second cathode portion 182 are provided in the cathode region 82 as described below, switching loss can be reduced by lowering a value of the steady-state loss Vf that has increased due to having the second cathode portion 182 by adding the plug region 83.

FIG. 2C is an example of a c-c′ cross section in FIG. 1. The c-c′ cross section is a YZ plane passing through a center of a width of the trench contact portion 20 in the X axis direction in the diode portion 80. The semiconductor device 100 of the present example has the semiconductor substrate 10, the emitter electrode 52, and the collector electrode 24 on the c-c′ cross section.

The first cathode portion 181 is a region of the first conductivity type which has a higher doping concentration than that of the drift region 18. In an example, the first cathode portion 181 is of the N type. A width of the first cathode portion 181 in the trench extending direction (Y axis direction) may be greater than a width of the second cathode portion 182 in the trench extending direction.

The second cathode portion 182 is a region of the second conductivity type provided adjacent to the first cathode portion 181 on the back surface 23 of the semiconductor substrate 10. That is, the second cathode portion 182 may be in direct contact with the first cathode portion 181. In an example, the second cathode portion 182 is of the P type.

The first cathode portion 181 may be formed, by an ion implantation process for forming the second cathode portion 182, and by an ion of the dopant of the P type being implanted and then an ion of the dopant of the N type being implanted. Conversely, the second cathode portion 182 may be formed, by an ion implantation process for forming the first cathode portion 181, and by an ion of the dopant of the N type being implanted and then an ion of the dopant of the P type being implanted.

The first cathode portion 181 and the second cathode portion 182 are arranged so as to form a boundary in contact with each other. The first cathode portion 181 and the second cathode portion 182 may be alternately arranged in any direction. The first cathode portion 181 and the second cathode portion 182 of the present example are alternately arrayed in the trench extending direction (for example, the Y axis direction), but may be alternately arrayed in the trench array direction (for example, the X axis direction). The first cathode portion 181 and the second cathode portion 182 may be arranged in a striped pattern in a top view. One of the first cathode portion 181 and the second cathode portion 182 may be formed in a dotted pattern.

The cathode region 82 in the diode portion 80 of the present example has the first cathode portion 181 and the second cathode portion 182 arranged so as to form the boundary in contact with each other. By providing the first cathode portion 181 and the second cathode portion 182 in the cathode region 82, voltage overshoot is lowered, reverse recovery loss Err of the diode portion can be shortened, and the reverse recovery loss Err can be reduced.

In addition, the semiconductor device 100 of the present example is provided with the second accumulation region 26 in the boundary region 90. By providing the second accumulation region 26, a trade-off curve between the reverse recovery loss Err and the steady-state loss Vf can be adjusted in a direction in which the reverse recovery loss Err is reduced. By using the second accumulation region 26, and the first cathode portion 181 and the second cathode portion 182 in combination, the reverse recovery loss Err and the steady-state loss Vf can be finely adjusted to suit a required performance.

The semiconductor device 100 of the present example does not have a lifetime killer region inside the semiconductor substrate 10. In general, by providing the lifetime killer region in both the transistor portion 70 and the diode portion 80, hole injection from the transistor portion 70 can be suppressed, and the reverse recovery loss Err can be reduced. In the present example, by providing the trench contact portion 20 instead of providing the lifetime killer region, the reverse recovery loss Err is reduced.

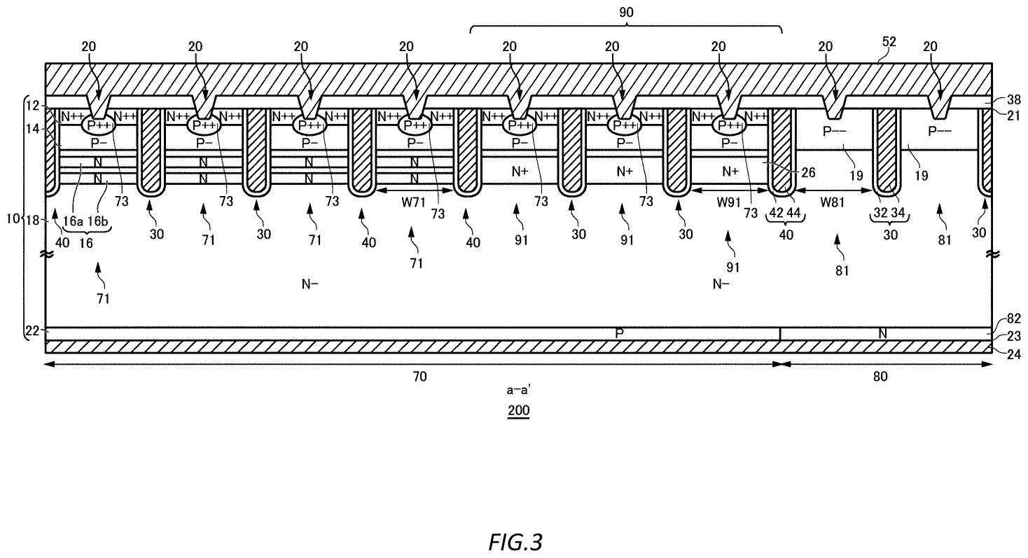

FIG. 3 is a modification example of the a-a′ cross section in FIG. 1. On the a-a′ cross section of FIG. 3, the second accumulation region 26 is provided in one stage. In the modification example of FIG. 3, the thickness of the second accumulation region 26 in the depth direction of the semiconductor substrate 10 is smaller than the thickness of the first accumulation region 16 in the depth direction of the semiconductor substrate 10. The second accumulation region 26 may be provided so that a position of the lower end is positioned above the bottom portion of the adjacent gate trench portion 40.

The second accumulation region 26 in the modification example of FIG. 3 does not have a peak of the doping concentration, and may be provided so that a distribution of the doping concentration becomes broad. The distribution of the doping concentration being broad may mean that, by changing an acceleration voltage for implanting a dopant and implanting it in multiple separate steps, an amount of change in the doping concentration is 5% or less over a range of 1.0 μm or more and 3.5 μm or less, or is 5% or less over a range of 90% of the thickness of the second accumulation region 26. By providing the second accumulation region 26 so that the distribution of the doping concentration thereof becomes broad, the clamp tolerance can be further improved compared to when the second accumulation region 26 is provided in multiple stages.

In the present example, a pitch width W91 of the boundary mesa portion 91 of the boundary region 90 is the same as a pitch width W71 of the mesa portion 71 of the transistor portion and a pitch width W81 of the mesa portion 81 of the diode portion. The pitch width W91 of the boundary mesa portion 91 may be wider than the pitch width W71 of the transistor portion and the pitch width W81 of the diode portion. By making the pitch width W91 of the boundary mesa portion 91 wider than the pitch width W71 of the transistor portion and the pitch width W81 of the diode portion, implantation of holes into the diode portion 80 can be suppressed, and the reverse recovery loss Err can be reduced.

In the present example, the boundary region 90 is provided over a plurality of mesa portions. In the trench array direction (X axis direction) of the plurality of trench portions, the width of the boundary region 90 may be 30 μm or more and 150 μm or less.

Similarly to the semiconductor device 100, a semiconductor device 200 of the present example does not have a lifetime killer region inside the semiconductor substrate 10. In general, by providing the lifetime killer region in both the transistor portion 70 and the diode portion 80, hole injection from the transistor portion 70 can be suppressed, and the reverse recovery loss Err can be reduced. In the present example, by providing the trench contact portion 20 instead of providing the lifetime killer region, the reverse recovery loss Err is reduced.

Although it is not illustrated, in the transistor portion 70, a trench bottom region of the second conductivity type formed on the lower ends of the gate trench portion 40 and the dummy trench portion 30 so as to cover the bottom portion and a part of a side surface of the trench portions may be provided. The trench bottom region is provided so as to not come in contact with either the first accumulation region 16 or the second accumulation region 26. The trench bottom region is of the P+ type as an example. A doping concentration of the trench bottom region may be a doping concentration equal to or higher than that of the base region 14 and equal to or lower than that of the contact region 15. By providing the trench bottom region, an electric field strength of the trench portion bottom portion can be reduced.

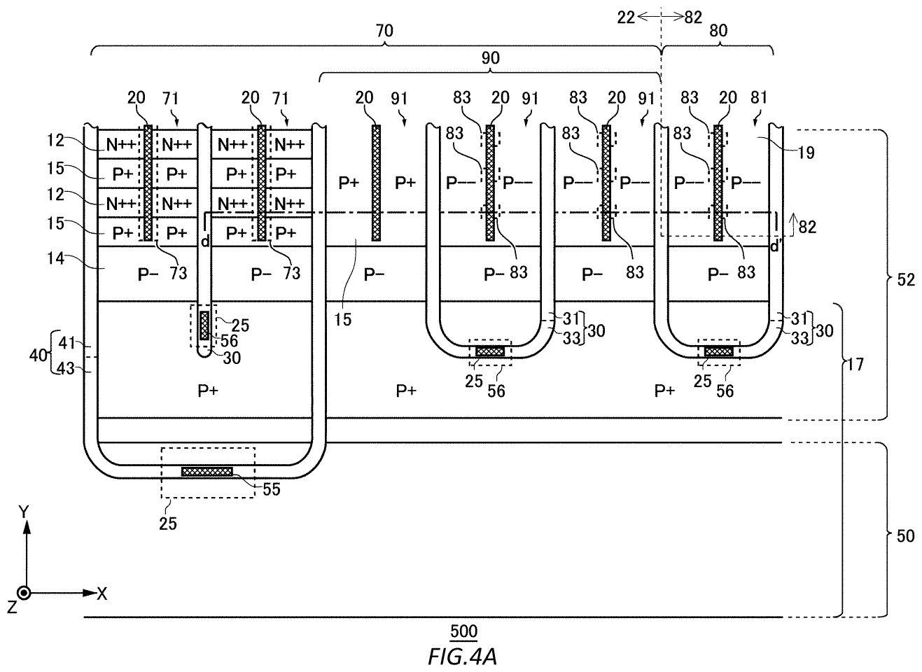

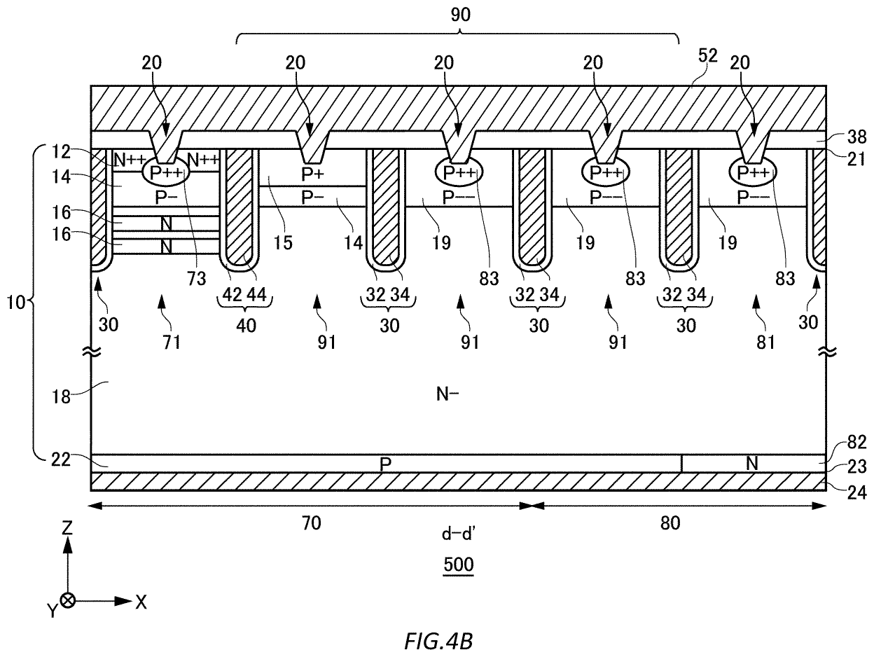

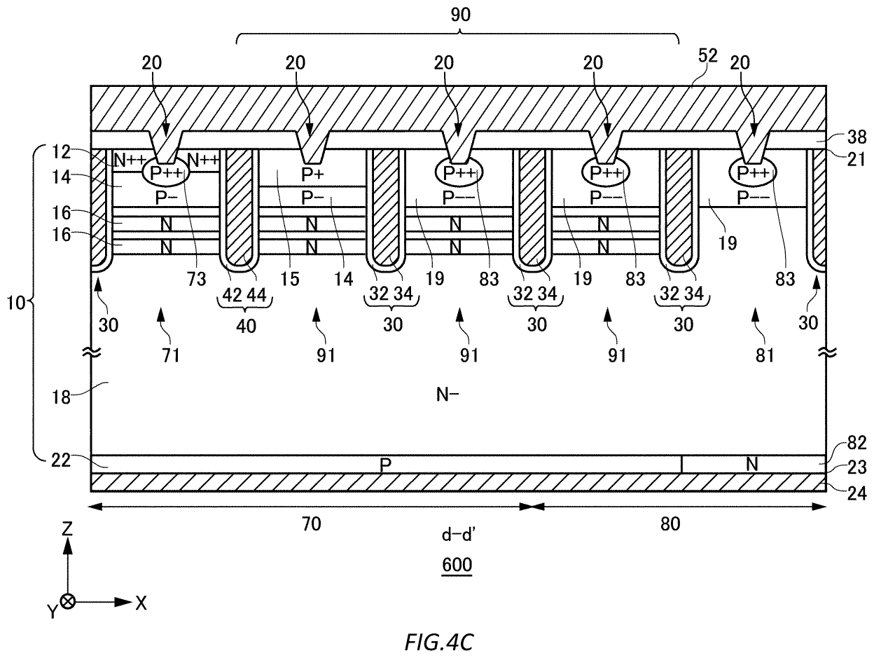

FIG. 4A illustrates an example of a top view of a semiconductor device 500 of a comparative example 1. FIG. 4A differs from the embodiment in FIG. 1 in that the boundary region 90 does not have the emitter region 12 and is provided with the dummy trench portion 30.

In the semiconductor device 500 of the comparative example 1, since the boundary region 90 does not have the emitter region 12, the boundary region 90 cannot function as the active region. In the semiconductor devices 100 and 200 of the present example, since the emitter region 12 is also provided in the boundary region 90, the area of the active region of the transistor portion 70 can be increased compared to the semiconductor device 500 of the comparative example 1.

FIG. 4B is an example of a d-d′ cross section in FIG. 4A. A line d-d′ corresponds to a line b-b′ in FIG. 1. In the semiconductor device 500 of the comparative example 1 illustrated in FIG. 4B, the second accumulation region 26 is not provided in the boundary region 90. In the semiconductor devices 100 and 200 in the present example, by providing the second accumulation region 26 in the boundary region 90, hole injection from the transistor portion 70 can be suppressed, and the reverse recovery loss Err can be reduced.

FIG. 4C is a modification example of the d-d′ cross section in FIG. 4A. A semiconductor device 600 of a comparative example 2 illustrated in FIG. 4C differs from the semiconductor device 500 of the comparative example 1 illustrated in FIG. 4B in that the first accumulation region 16 is provided in the boundary region 90. Since the semiconductor device 600 of the comparative example 2 is provided with the first accumulation region 16 in the boundary region 90, hole injection from the transistor portion 70 can be suppressed, and the reverse recovery loss Err can be reduced more than in the semiconductor device 500 of the comparative example 1.

In the semiconductor device 600 of the comparative example 2 illustrated in FIG. 4C, since the emitter region 12 is not provided in the boundary region 90, the boundary region 90 cannot operate as the active region. In the semiconductor devices 100 and 200 of the present example, since the emitter region 12 is provided in the boundary region 90, the area of the active region of the transistor portion 70 can be increased compared to the semiconductor device 600 of the comparative example 2.

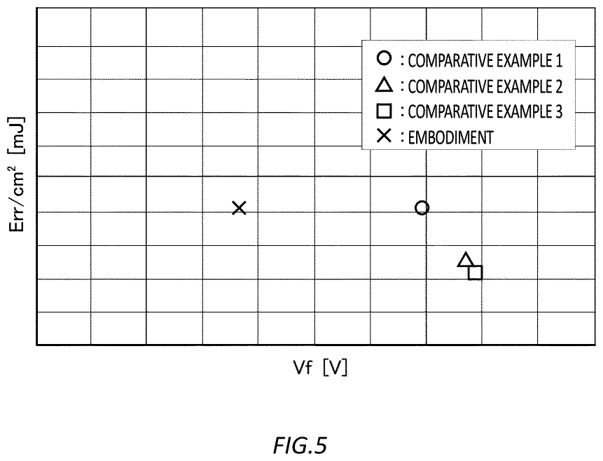

FIG. 5 is a graph showing a relationship between the steady-state loss Vf and the reverse recovery loss Err. In the figure, the comparative example 1 indicated by a circular mark corresponds to the semiconductor device 500 of the comparative example 1 illustrated in FIG. 4B, and the comparative example 2 indicated by a triangular mark corresponds to the semiconductor device 600 of the comparative example 2 illustrated in FIG. 4C. In addition, a comparative example 3 indicated by a square mark is obtained by increasing the doping concentration of the first accumulation region 16 in the semiconductor device 600 illustrated in FIG. 4C more than the comparative example 2.

When the comparative example 1 and the comparative example 2 of FIG. 5 are compared, it can be seen that by providing the first accumulation region 16 in the boundary region 90, the steady-state loss Vf slightly increases, and the reverse recovery loss Err is reduced. In addition, when the comparative example 2 and the comparative example 3 are compared, it can be seen that by increasing the doping concentration of the first accumulation region 16, the reverse recovery loss Err can be further reduced.

As indicated by an x mark in FIG. 5, the semiconductor device 100 of the present example, compared to the comparative example 1, can suppress hole injection from the transistor portion 70 to the diode portion 80, and can further reduce the steady-state loss Vf relative to the comparative examples 1, 2, and 3, while maintaining the reverse recovery loss Err. In addition, since the boundary region 90 in the semiconductor device 100 of the present example can function as the active region, operation efficiency improves compared to the comparative examples 1, 2, and 3.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments to which such alterations or improvements are made can be included in the technical scope of the present invention.

It should be noted that the operations, procedures, steps, stages, or the like of each process performed by a device, system, program, and method shown in the claims, the specification, or the drawings can be performed in any order as long as the order is not indicated by “prior to,” “before,” or the like and as long as the output from a previous process is not used in a later process. Even if the process flow is described by using phrases such as “first” or “next” in the claims, the specification, or the drawings for the sake of convenience, it does not necessarily mean that the process must be performed in this order.

### EXPLANATION OF REFERENCES

10 semiconductor substrate; 12 emitter region; 14 base region; 15 contact region; 16 first accumulation region; 17 well region; 18 drift region; 19 anode region; 20 trench contact portion; 21 front surface; 22 collector region; 23 back surface; 24 collector electrode; 25 connecting portion; 26 second accumulation region; 30 dummy trench portion; 31 extending part; 32 dummy dielectric film; 33 connecting part; 34 dummy conductive portion; 38 interlayer dielectric film; 40 gate trench portion; 41 extending part; 42 gate dielectric film; 43 connecting part; 44 gate conductive portion; 50 gate metal layer; 52 emitter electrode; 55 contact hole; 56 contact hole; 70 transistor portion; 71 mesa portion; 73 plug region; 75 main region; 80 diode portion; 81 mesa portion; 82 cathode region; 181 first cathode portion; 182 second cathode portion; 83 plug region; 90 boundary region; 91 mesa portion; 100 semiconductor device; 200 semiconductor device; 500 semiconductor device; 600 semiconductor device.

What is claimed is:

1. A semiconductor device comprising a transistor portion and a diode portion, the semiconductor device comprising:
a plurality of trench portions provided at a front surface of a semiconductor substrate and including a gate trench portion;
a drift region of a first conductivity type provided in the semiconductor substrate;
a base region of a second conductivity type provided above the drift region;
an emitter region of the first conductivity type provided above the base region and having a doping concentration higher than that of the drift region;
a first accumulation region of the first conductivity type provided below the base region and having a doping concentration higher than that of the drift region; and
a contact region of the second conductivity type provided above the base region and having a doping concentration higher than that of the base region, wherein
the transistor portion has a boundary region which includes a boundary mesa portion sandwiched between the plurality of trench portions and which is provided in direct contact with the diode portion, wherein the boundary region includes:
the emitter region provided in the boundary mesa portion;
a second accumulation region of the first conductivity type provided in the boundary mesa portion and having a doping concentration higher than that of the first accumulation region; and
the gate trench portion provided in contact with the boundary mesa portion.

2. The semiconductor device according to claim 1, wherein
the doping concentration of the second accumulation region is lower than the doping concentration of the emitter region.

3. The semiconductor device according to claim 1, wherein
the doping concentration of the second accumulation region is 1E16 cm⁻³ or more and 1E20 cm⁻³ or less.

4. The semiconductor device according to claim 1, wherein
the second accumulation region has a plurality of peaks of a doping concentration in a depth direction of the semiconductor substrate.

5. The semiconductor device according to claim 1, wherein
the second accumulation region has one peak of a doping concentration in a depth direction of the semiconductor substrate.

6. The semiconductor device according to claim 5, wherein
a thickness of the second accumulation region in the depth direction of the semiconductor substrate is 0.5 μm or more and 4.0 μm or less.

7. The semiconductor device according to claim 1, wherein
the diode portion does not have either the first accumulation region or the second accumulation region.

8. The semiconductor device according to claim 1, wherein
a mesa width of the boundary mesa portion is greater than a mesa width of a mesa portion other than the boundary mesa portion in a trench array direction of the plurality of trench portions.

9. The semiconductor device according to claim 1, wherein
a width of the boundary region in a trench array direction of the plurality of trench portions is 30 μm or more and 150 μm or less.

10. The semiconductor device according to claim 1, comprising a trench contact portion provided at the front surface of the semiconductor substrate.

11. The semiconductor device according to claim 10, wherein
in the transistor portion, a position of a lower end of the trench contact portion is shallower than a position of a lower end of the emitter region in a depth direction of the semiconductor substrate.

12. The semiconductor device according to claim 10, comprising a plug region of the second conductivity type provided in contact with a bottom surface of the trench contact portion and having a doping concentration higher than that of the base region.

13. The semiconductor device according to claim 12, wherein
in the transistor portion, the plug region is provided extending in a trench extending direction of the plurality of trench portions.

14. The semiconductor device according to claim 12, wherein
in the diode portion, a plurality of plug regions including the plug region are provided discretely in a trench extending direction of the plurality of trench portions.

15. The semiconductor device according to claim 1, wherein
the diode portion includes a cathode region of the first conductivity type having a doping concentration higher than that of the drift region at a back surface of the semiconductor substrate, and
the cathode region includes a first cathode portion of the first conductivity type and a second cathode portion of the second conductivity type.

16. The semiconductor device according to claim 1, comprising
an anode region of the second conductivity type provided closer to the front surface of the semiconductor substrate than the drift region in the diode portion.

17. The semiconductor device according to claim 16, wherein
a doping concentration of the anode region is lower than the doping concentration of the base region.

18. The semiconductor device according to claim 1, wherein
the semiconductor device does not have a lifetime killer region inside the semiconductor substrate.

19. The semiconductor device according to claim 1, wherein
the boundary region includes the contact region provided in the boundary mesa portion, and
in the boundary mesa portion, the emitter region and the contact region are alternately arranged in a trench extending direction of the plurality of trench portions.

20. The semiconductor device according to claim 1, wherein
the second accumulation region does not have a peak of a doping concentration in a depth direction of the semiconductor substrate.
